(19) United States
(12) Patent Application Publication
(10) Pub. No.: US 2025/0199062 A1
(43) Pub. Date: Jun. 19, 2025

(54) Systems, Methods, and Devices of Droop Detector Circuitry

(71) Applicant: Arm Limited, Cambridge (GB)

(72) Inventors: El Mehdi Boujamaa, Valbonne (FR); Franck Gregory Ciotti, Nice (FR)

(21) Appl. No.: 18/985,268

(22) Filed: Dec. 18, 2024

(30) Foreign Application Priority Data
Dec. 18, 2023 (GB) 2319374.1

(51) Int. Cl. G01R 31/30; G01R 19/165; G06F 1/06; H03K 5/00; H03K 5/131; H03K 5/133; H03K 5/135

(52) U.S. Cl. CPC G01R 31/3004; G01R 19/16528; G06F 1/06; H03K 5/131; H03K 5/133; H03K 5/135; H03K 2005/00058

(57) ABSTRACT

According to one implementation, a circuit includes a droop detection element (112) including voltage sensitive gates (114A-N) and at least two delay elements (118A, 118B) where each delay element of the at least two delay elements is a non-inverting gate or a non-inverting gate combination. The at least two delay elements (118A, 118B) are configured to provide a delay to the droop detection element (112), where at least a first delay element (118A) is a first voltage-threshold (VT)-type, at least a second delay element (118B) is a second voltage-threshold (VT)-type, and the first and the second VT-types are different.

### FIELD

The present disclosure is generally related to the systems, methods, and devices of a droop detector circuit.

### DESCRIPTION OF RELATED ART

This section is intended to provide information relevant to understanding various technologies described herein. As the sections heading implies, this is a discussion of related art that in no way implies that the discussion is prior art. Generally, related art may or may not be considered prior art. Any statement in this section should be read in this light, and not as admission of prior art.

Droop detectors and delay monitors are both gate delay-based voltage droop sensors that play roles in maintaining the reliable and accurate operation of digital systems. Differentially, a droop detector focuses on voltage stability and a delay monitor focuses on timing and synchronization within a system. In applications, droop detectors and delay monitors are often used in, for example, high-speed communication, signal processing, and precision control systems.

### BRIEF DESCRIPTION OF THE DRAWINGS

Implementations of various techniques are described herein with reference to the accompanying drawings. The accompanying drawings illustrate various implementations described herein and are not meant to limit implementations of various techniques described herein.

FIG. 1 is a diagram, in accordance with certain implementations.

FIG. 2 is a diagram, in accordance with certain implementations

FIG. 3 is a diagram, in accordance with certain implementations.

FIG. 4A is a representation, in accordance with certain implementations.

FIG. 4B is a representation, in accordance with certain implementations.

FIG. 4C is a representation, in accordance with certain implementations.

FIG. 4D is a representation, in accordance with certain implementations.

FIG. 5 is a diagram, in accordance with certain implementations.

FIG. 6 illustrates an example procedure, in accordance with certain implementations.

FIG. 7 is a diagram, in accordance with certain implementations.

Reference is made in the following detailed description to accompanying drawings, that form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other implementations may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, and the like), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

According to one implementation of the present disclosure, a (droop detector) circuit includes a droop detection element comprising voltage sensitive gates, at least two delay elements where each delay element of the at least two delay elements include a non-inverting gate or a non-inverting gate combination. At least a first delay element includes a first voltage-threshold (VT)-type, at least a second delay element includes a second VT-type, and the first and the second VT-types are different. The at least two delay elements are configured to provide a delay to the droop detection element.

According to another implementation of the present disclosure, a method includes providing, by a plurality of delay elements with voltage sensitive gates of a delay monitor, a droop detection element, providing, by a plurality of delay elements of a delay circuit, a clock signal and delayed versions of the clock signal, wherein one or more of the delay elements have different VT-types, selecting, by a selection device, the clock signal or one of the delayed versions of the clock signal, and transmitting, by a multiplexer, the clock signal or the one of the delayed versions of the clock signal to the droop detection element.

According to another implementation of the present disclosure, a computing system includes one or more processors, and at least one memory that includes program instructions executable by the one or more processors to provide, by a plurality of delay elements with voltage sensitive gates of a delay monitor, a droop detection element, provide, by a plurality of delay elements of a delay circuit, a clock signal and delayed versions of the clock signal where one or more of the delay elements have different VT-types, select, by a selection device, the clock signal or one of the delayed versions of the clock signal, and transmit, by a multiplexer, the clock signal or the one of the delayed versions of the clock signal to the droop detection element.

Schemes and techniques relate to an inventive droop detector providing clarity in measurement of logic depth of a critical path with two or more delay elements that include a voltage threshold (VT) type that is the same or similar to a VT-type of logic gates in a critical path. Advantageously, the two or more delay elements are configured to track the critical path with a “high” (e.g., greater than 50%) percentage of accuracy. Additional schemes and techniques relate to the inventive droop detector that includes a droop detection element with voltage sensitive gates configured to detect a voltage variation from a voltage feed to the droop detection element by the one or more delay elements. Advantageously, the droop detection element can detect a voltage droop before the voltage droop affects the critical path.

Certain definitions have been provided herein for reference. In digital circuitry, a delay element refers to a component or sub-circuit intentionally configured to introduce a specific delay in the propagation of a signal passing through the delay element. Functionally, these delay elements may be used in managing signal timing, synchronization, and ensuring proper functionality within a circuit. Purposefully, delay elements intentionally slow down or delay the propagation of signals in a digital circuit. In certain implementations of the present disclosure, delay elements are buffers leveraging inherent propagation delay. However, one or ordinary skill in the art understands a delay element can be an RC circuit of resistors and capacitors introducing delay based on the charging/discharging time of the capacitor, configurations of inverters or gates in a loop to create oscillations (such as a ring oscillator) offering a delayed output based on the oscillation frequency, transmission lines utilized to introduce controlled delays such as in high-frequency applications, and the like without departing from the spirit of the implementations.

In some implementations, one or more delay elements are arranged in a delay chain. In some other implementations, the one or more delay elements are arranged in an interleaved delay element chain. Furthermore, an interleaved delay element chain is a design technique that can be used in digital circuits, particularly in timing-related applications, to achieve precise and programmable delays by interleaving multiple delay elements. The interleaved delay element chains are utilized to create precise and programmable delays in digital circuits, essential for meeting timing requirements, synchronization, or signal alignment. As the interleaved name implies, the delay element chain includes multiple delay elements arranged in an interleaved fashion. By interleaving or alternating different delay elements, the overall delay chain achieves more precise and finer resolution in delay increments and a larger range of selectable delay values. Advantageously, interleaved delay element chains provide the ability to adjust delays dynamically, allowing adaptation to changing operational requirements.

In digital circuitry, a delay monitor can measure the logic depth of a critical path and operating as a telemetry sensor collect and transmit data from remote or inaccessible locations to a centralized location for monitoring, analysis, and/or control purposes. Depending on specific designs and application purposes, telemetry sensors are equipped to measure various physical parameters such as temperature, pressure, humidity, acceleration, position, and more.

In digital circuitry and computer architecture, a critical path refers to the “longest” (i.e., in temporal terms) path taken by signals through combinational (refers to a type of logic circuit where the output is determined solely by the current combination of inputs at that instant) logic elements (such as logic gates, multiplexers, and the like) and sequential elements (like flip-flops or registers) in a digital system. Further, the critical path determines the maximum delay for the propagation of a signal from source to destination within the circuit.

In a central processing unit (CPU) (e.g., the primary component of a computer responsible for executing instructions, performing calculations, and managing data within a computer system), the critical path involves logic gates that during a first clock period of a clock input (ckin) (the time interval between consecutive rising (or falling) edges), at the rising edge of the clock input (ckin), a signal at the input of a logic gate shifts (or is transmitted) to the output. Repeatedly, this process continues by many more logic gates and once the signal is processed, the signal is outputted with a given delay. It is beneficial that the given delay is lower than a clock period (e.g., a period of the clock input (ckin)) so that the following rising edge can “catch” (i.e., the timing of the rising edge of the clock signal is such that it arrives precisely when the signal propagation through the logic gates reaches the end of its path) the signal at an end of signal logic gates.

In the CPU, there are millions of logic paths, however crucial paths, such as the critical path may be defined as the input of signal logic gates to an end of signal logic gates being a duration “close” to (approximately that of) a clock period. In response to a voltage drop, caused by the logic gates that process the signal between the end of signal logic gates, a delay of the signal increases as voltage is used to process the signal from the input of the signal logic gates to the output of the end of signal logic gates. In response to the delay, and considering the clock period has not changed, the processed data of the signal may not be “caught” by the end of signal logic gates. In response to the signal arriving at a logic gate outside of the gate's specified timing window (e.g., either too early or too late), the logic gate might not recognize or “capture” the signal properly, and that can make the CPU crash or process incorrect data.

To guarantee critical paths are met, some voltage variation margin (e.g., referring to the acceptable range or tolerance within which a circuit or device can operate reliably despite fluctuations or variations in the supply voltage) is used with place and route tools (e.g., software tools used in the design and manufacturing of integrated circuits (ICs) or chips which play a role in the physical design phase of creating electronic chips, optimizing the layout of components on a semiconductor chip, and establishing the paths for electrical connections) to satisfy frequency requirements. However, the circuit or device may use excessive voltage variation margins, and therefore the CPU would not function optimally. Therefore, reducing voltage variation margins can be beneficial.

In digital circuitry, logic depth refers to the maximum number of logical stages or levels through that a signal or data passes in a digital circuit from an input to an output. Traversing through the various stages of logic gates or components within a circuit the logic depth represents the cumulative delay or processing time experienced by a signal. In a complex digital circuit, signals often pass through multiple logic gates (e.g., such as AND, OR, and/or NOT gates) and other components. Propagation delay is introduced by each gate, that is, the time taken for the input signal to produce the output signal. Signal progression through successive gates results in accumulating delays contributing to the total propagation delay experienced by the signal from an input to an output. Longer propagation delays affecting the circuits speed and performance are the result of excessive logic depth. In optimizing circuit design to minimize delays and improve performance, identification of the critical path, that is the path through the circuit that experiences the longest delay, is a factor in digital circuit design.

In the context of semiconductor technology, as defined herein, particularly related to MOSFETs (Metal-Oxide-Semiconductor Field-Effect Transistors) or CMOS (Complementary Metal-Oxide-Semiconductor) devices, “VT-type” refers to the threshold voltage type of a MOSFET. To allow current to flow through a transistor, the threshold voltage (VT) represents the minimum voltage applied to the gate of a MOSFET to induce current flow in a channel between the transistor source and drain regions. As indications of different threshold voltage levels, MOSFETs have different threshold voltage types and categories, such as “low VT” (e.g., an ultra-low voltage threshold (ULVT) or an extra-low voltage threshold (ELVT)) and “high VT,” (e.g., such as above an ultra-low voltage threshold (ULVT) or an extra-low voltage threshold (ELVT) but below a standard voltage threshold (SVT)). Based on threshold voltage characteristics that affect performance and behavior in circuit designs, VT-type categorization classifies MOSFETs. Further, MOSFETs with a lower threshold voltage (e.g., typically below an SVT, such as ULVT and ELVT) may often be used in designs requiring faster switching speeds and higher performance, but may consume more power at idle states. In contrast, MOSFETs with a higher threshold voltage (e.g., above an SVT) are useful for reducing leakage currents, enhancing power efficiency, and maintaining stability in certain circuit configurations. In many electronic devices, components, or circuits, there exist voltage thresholds (VT) that determine when certain actions or functions occur. For example, in digital circuits, there are voltage thresholds (VT) that distinguish between logic levels (e.g., 0 and 1 in binary systems). Certain actions, such as switching states, amplifying signals, or enabling specific functionalities can be initiated by components like transistors, operational amplifiers, or integrated circuits (ICs) that often have a VT that is met or exceeded.

An ultra-low voltage threshold (ULVT) or extra-low voltage threshold (ELVT) refers to the voltage level at a device, typically a transistor or semiconductor component, operates at or switch states. In the context of transistors, as defined herein, a low voltage threshold implies that the transistor turns “on” or “off” with very low voltage levels. A ULVT or an ELVT designation signifies that the transistors effectively switch or conduct at significantly lower voltage levels than traditional transistors. Advantageously, these transistors include higher switching speed, increased energy efficiency, and the ability to operate in low-power or energy-harvesting applications where power availability is limited. As an example of application usage, such transistors can be used in various fields, including IoT devices, wearable electronics, medical implants, and sensor networks, where operating at ultra-low voltages is useful to extending battery life or functioning with minimal power resources.

In the context of semiconductor technology, as defined herein, voltage sensitivity refers to the response or change in a device's behavior or output in relation to variations in voltage levels applied. How a device, circuit, or component reacts or responds to changes in voltage is a measure of voltage sensitivity.

In digital circuitry, predictability in circuit design refers to the ability to foresee and anticipate the behavior, performance, and characteristics of a circuit based on design, specifications, and operating conditions. A predictable circuit is one where the output response or behavior can be reliably determined or forecasted based on the inputs, component specifications, and known characteristics of the circuit elements.

In an example operation, in response to an operating signal voltage (e.g., a voltage level used to power active components within a circuit) being at or near a maximum, the number of logic gates that a signal voltage can propagate through from a first rising edge to a second rising edge of the signal voltage is approximately 30 logic gates. In response to the signal voltage decreasing (i.e., a voltage droop), as the signal propagates through the logic gates, then the number of logic gates that can be propagated through decreases (e.g., from 30 to 25, then 21, and then 19). As a result of the voltage droop, the number of logic gates that can be propagated through in a clock period is decreasing as each digital gate is getting “slower”, that is each logic gate is taking “longer” to reach a respective voltage threshold as the voltage droops.

Thus, there is a desire to predict the number of logic gates that can be propagated through to know the impact of the voltage droop on the critical path. In certain limitations, a droop detection element with voltage sensitive gates anticipates the transition between logic gates before the impact of a respective voltage droop on the critical path. Advantageously, the inventive droop detection circuit can react and take preventative measures, for example, in response to the critical path being X number of logic gates and the droop detection element indicates a switch from N+X logic gates to X gates. Hence, the droop detection circuit can be “aware” that there could be an issue on the critical path.

In certain implementations, to predict an issue, such as voltage droop on a critical path, digital logic gates in a droop detector element are configured with a greater voltage sensitivity than the digital logic gates in the critical path. Therefore, the digital logic gates in the droop detector element transition earlier, that is detect a voltage droop before the impact of the voltage droop on the critical path. Thus, in one advantage, anticipatory of issues in the critical path, manipulating the voltage sensitivity provides a predictive capacity to react to such issues (e.g., by reducing a clock frequency, and the like).

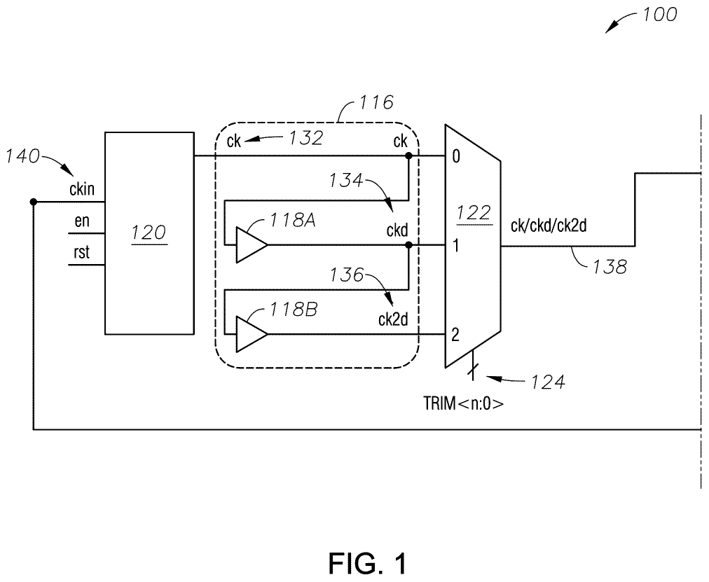

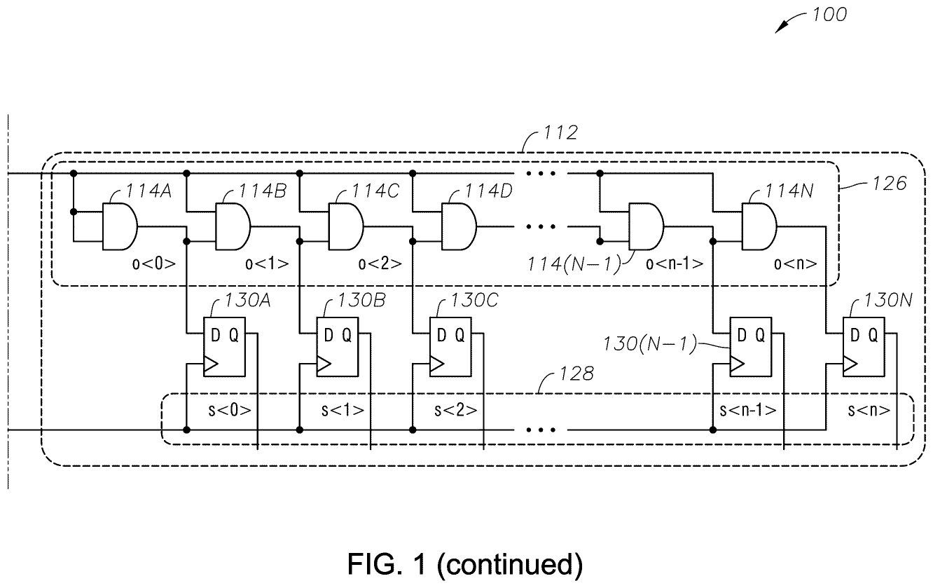

FIG. 1 is a block diagram representation of an example droop detector circuit 100 with an example up-front delay line 116, in accordance with certain implementations.

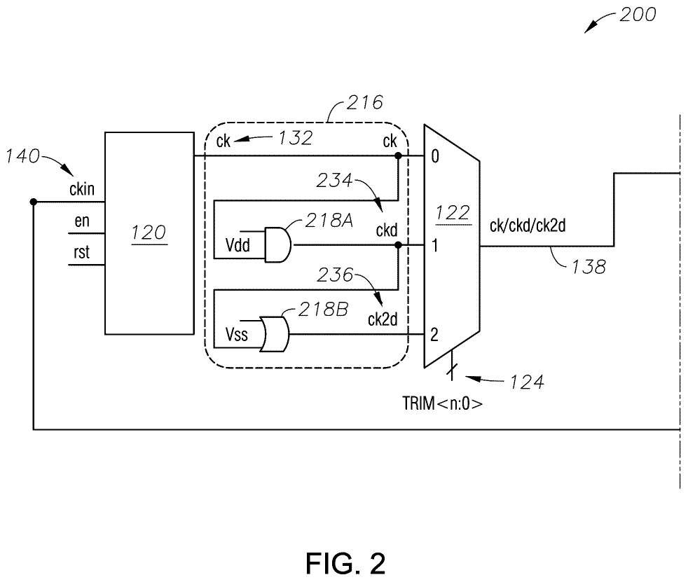

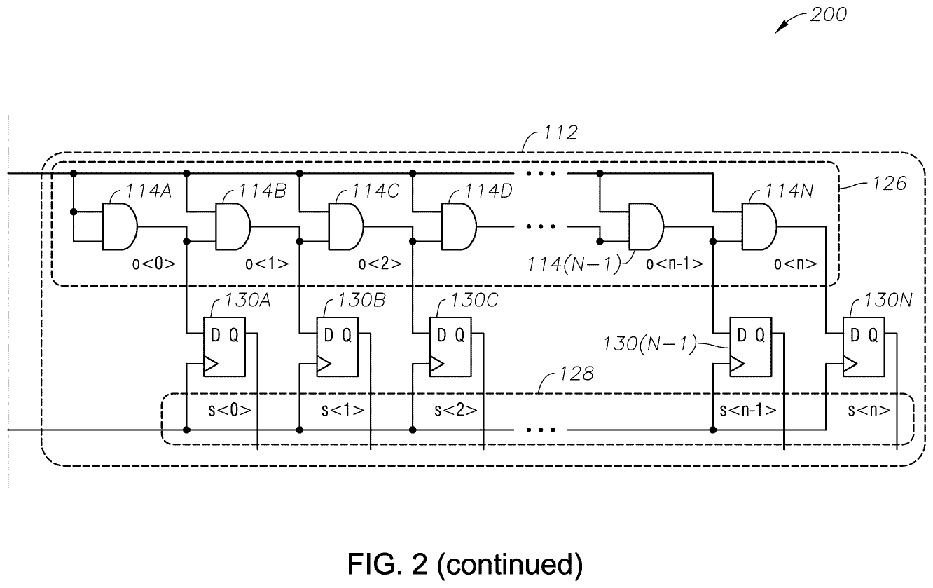

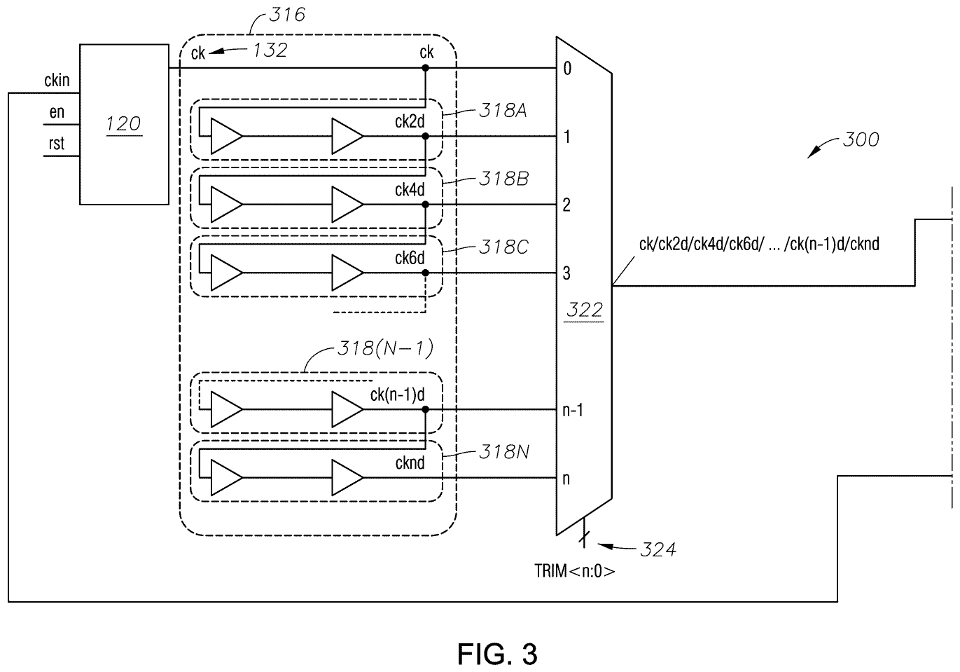

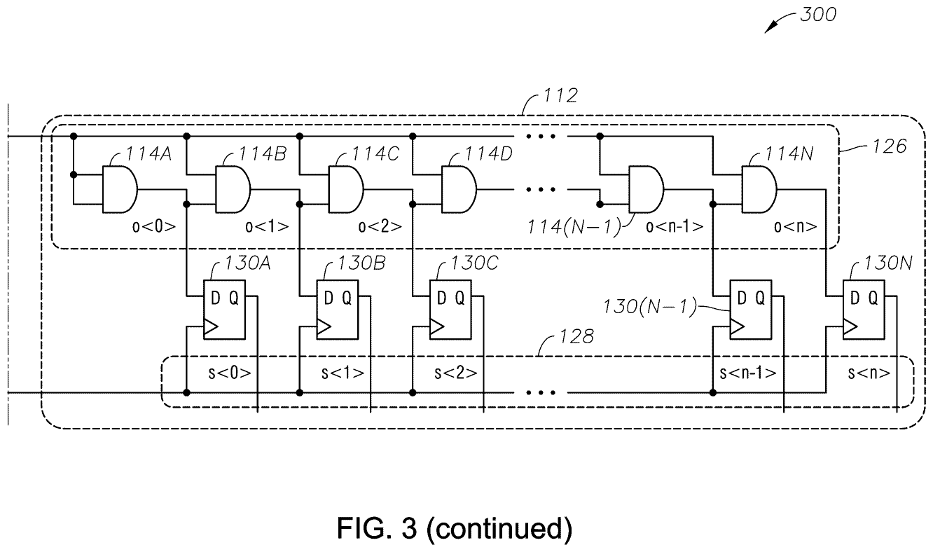

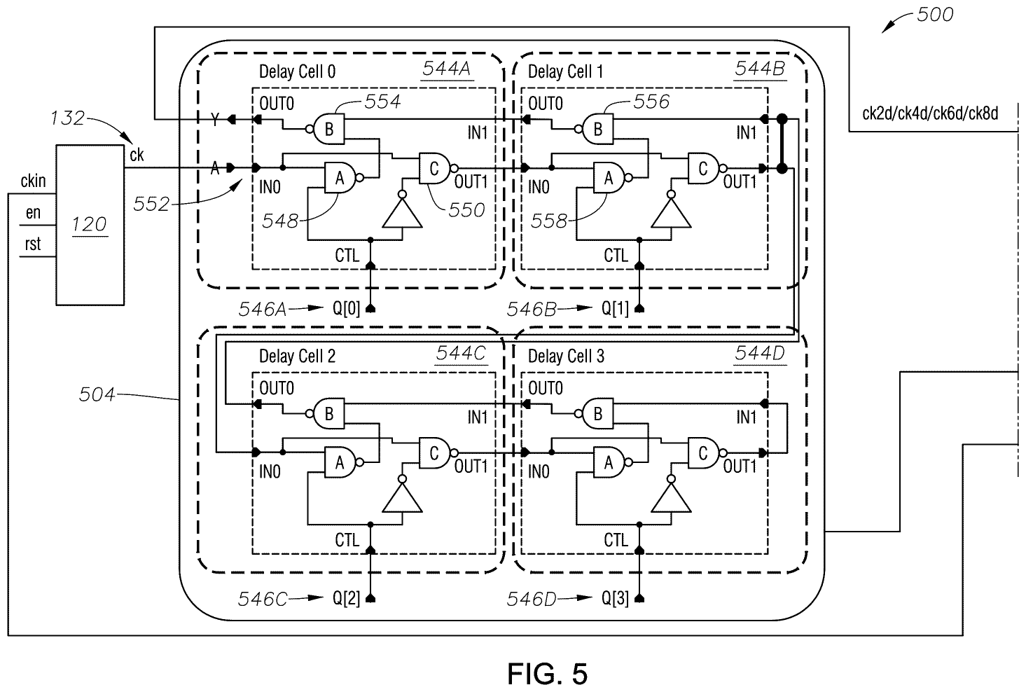

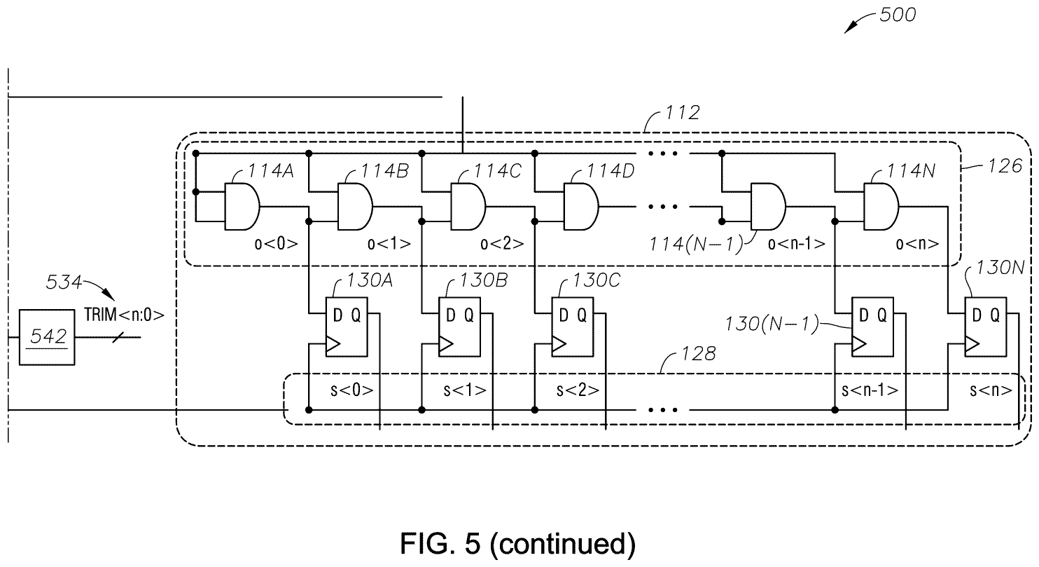

In various implementations, each of the example droop detector circuits 100, 200 (FIG. 2), 300 (FIG. 3), and 500 (FIG. 5) in FIGS. 1B, 2, 3, and 5 can be implemented as a system or a device having various IC components that are arranged and coupled together as an assemblage or combination of parts that provide for a physical circuit design and related structures. Further, each of the example droop detector circuits 100, 200 (FIG. 2), 300 (FIG. 3), and 500 (FIG. 5) can be integrated with computing circuitry and related components on multiple chips, and further able to be implemented in various embedded systems, including but not limited to, for automotive, electronic, mobile, and Internet-of-things (IoT) applications.

As illustrated in FIG. 1, the example droop detector circuit 100 includes the example up-front delay line 116, a pulse generator 120, a multiplexer 122, and a droop detection element 112. The droop detection element 112 includes voltage sensitive gates, e.g., AND gates 114A, 114B, 114C, 114D, . . . , 114(N−1), and 114N, that have a VT-type unlike the digital logic gates in the critical path (of a separate processing unit as defined herein) (not shown). It is understood, AND gates produce an output signal in response to each input signal being at a digital logic high state (or 1). Further, in response to one AND gate input being a high digital state (1), the AND gate is a pass-through (e.g., in response to one AND gate input being at a high digital state (1), the gate allows the signal from the other input to “pass through” or affect the output) to the other AND gate input and the AND gate would output the input that is on the pass-through input.

In certain implementations, the example up-front delay line 116 includes delay elements 118A and 118B that are non-inverting gates or a non-inverting gate combination. A non-inverting gate is a type of logic gate that retains the same logical state as the input signal (clock signal (ck)) but performs other operations or functions. The simplest form of a non-inverting gate that amplifies or replicates the input signal without changing its logic level or logical state is a buffer. Another form of a non-inverting gate is a dual inverter. Yet another example of a non-inverting amplifier or buffer is an operational amplifier (op-amp) configured as a voltage follower. In various implementations, the delay element 118A has a VT-type of a first type and the delay element 118B has a VT-type of a second type where the first VT-type is different from the second VT-type. As discussed in detail below, the delay elements 118A and 118B are configured to provide a delay of clock signal (ck) to delay line 126. In certain implementations, the delay element 118A can be of a first VT-type such as a ULVT or ELVT type that corresponds to the critical path. Further, the delay element 118B can be of a second VT-type such as a standard voltage threshold (SVT) type configured for low voltage and low clock frequency operation. In various implementations, the first VT-type can be a lower voltage sensitivity than the second VT-type. In certain implementations, the delay elements 118A and 118B are AND gates, OR gates, or a combination of both (see, e.g., FIG. 2).

In various aspects, a pulse generator 120 can be configured to produce electrical pulses or waveforms such as a clock signal (ck) 132 with precise characteristics in terms of amplitude, duration, frequency, and shape. In one operation, the pulse generator 120 is configured to produce a pulse, such as clock signal (ck) 132, that is transmitted to the up-front delay line 116. As an example, the up-front delay line 116 may be an interleaved delay element chain that produces multiple outputs, such as the clock signal (ck) 132, a first delayed clock signal (ckd where d represents the clock signal propagating through the delay element 118A) 134, and a second delayed clock signal (ck2d where 2d represents the clock signal propagating through the delay elements 118A and 118B) 136.

To enable the pulse generator 120, an “en” input or enable input that serves as a control signal activates the pulse generator. In response to the “en” input being active (often driven to a digital logic high or digital logic low level, depending on the specific devices design), the “en” input allows the pulse generator 120 to operate and generate pulses according to configured settings. Resetting or initializing the pulse generator 120 to a predefined state is an “rst” input or reset input. In response to the “rst” input receiving a signal (such as a pulse, logic level change, or trigger), “rst” resets the internal state of the pulse generator 120, often clearing an ongoing operation or resetting configured parameters to their default values. Providing the timing reference for the pulse generation process is an input clock signal (ckin) 140 used to synchronize the generation of the clock signal (ck) 132, where the clock signal's timing or frequency is determined by the frequency of the input clock signal (ckin) 140.

In an implementation, the multiplexer 122 (MUX) is configured to select one of several input data lines (e.g., that receive inputs 0, 1, and 2) and route the inputs 0, 1, or 2 to an output line 138 based on control signals (e.g., a trim input 124). Selectable, based on the trim input 124, are: an input line 0 (where the input is the clock signal (ck) 132), an input line 1 (where the input is first delayed clock signal (ckd) 134), and an input line 2 (where the input is the second delayed clock signal (ck2d) 136) where each input to be selected are input to the multiplexer 122. Based on the trim input 124, the multiplexer 122 efficiently switches or selects between multiple input signals and transmits the selected signal to output line 138. Further, the trim input 124 determines the input line from input lines 0, 1, and 2, to be output to output line 138. Additionally, in certain cases, based upon the trim input 124, a delay (ts) is added (e.g., to the clock signal (ck) 132) or modified (e.g., either shortened, such as switching from the first delayed clock signal (ckd) 134 to the clock signal (ck) 132, or lengthened, such as switching from the first delayed clock signal (ckd) 134 to the second delayed clock signal (ck2d) 136). From one input of the inputs 0, 1, or 2 the multiplexer 122 selects and then transmits the selected input to the delay line 126. In response to the multiplexer 122 selecting the 2 input, clock signal (ck) 132 propagates through the delay elements 118A and 118B and the second delayed output signal (ck2d) 136 of the multiplexer 122 would be the combined delay (ts) from the delay elements 118A and 118B. In response to the multiplexer 122 selecting the 1 input, then clock signal (ck) 132 propagates through the delay element 118A before being inputted to delay line as the first delayed output (ckd) 134.

As illustrated in FIG. 1, the multiplexer 122 is configured to transmit to the delay line 126 (e.g., a delay monitor/telemetry sensor), either one of: the first delayed clock signal (ckd) 134 transmitted from the delay element 118A; the second delayed clock signal (ck2d) 136 transmitted from the delay element 118B, or the clock signal (ck) 132 with no-delay.

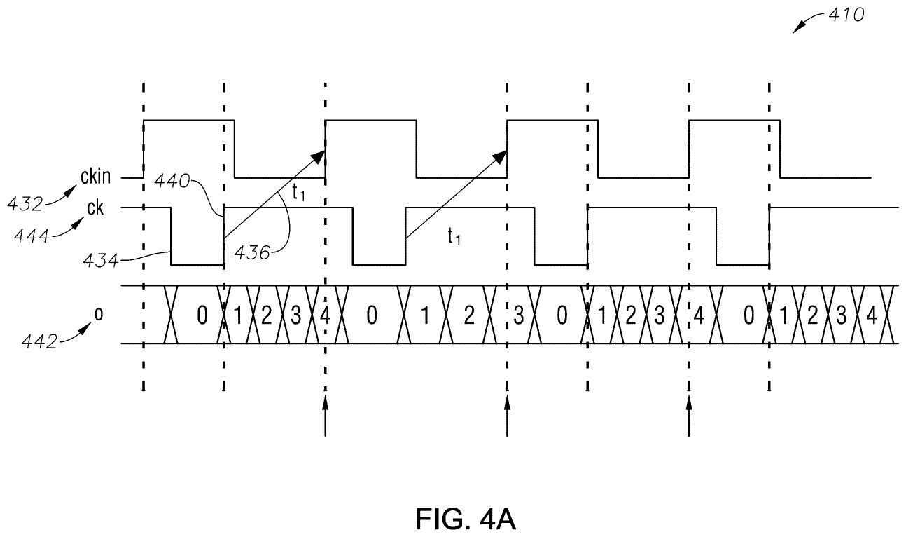

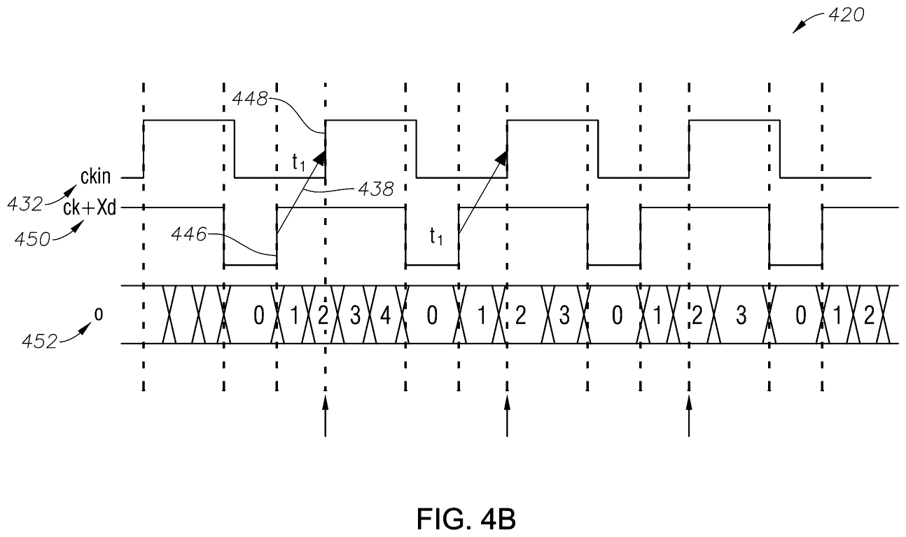

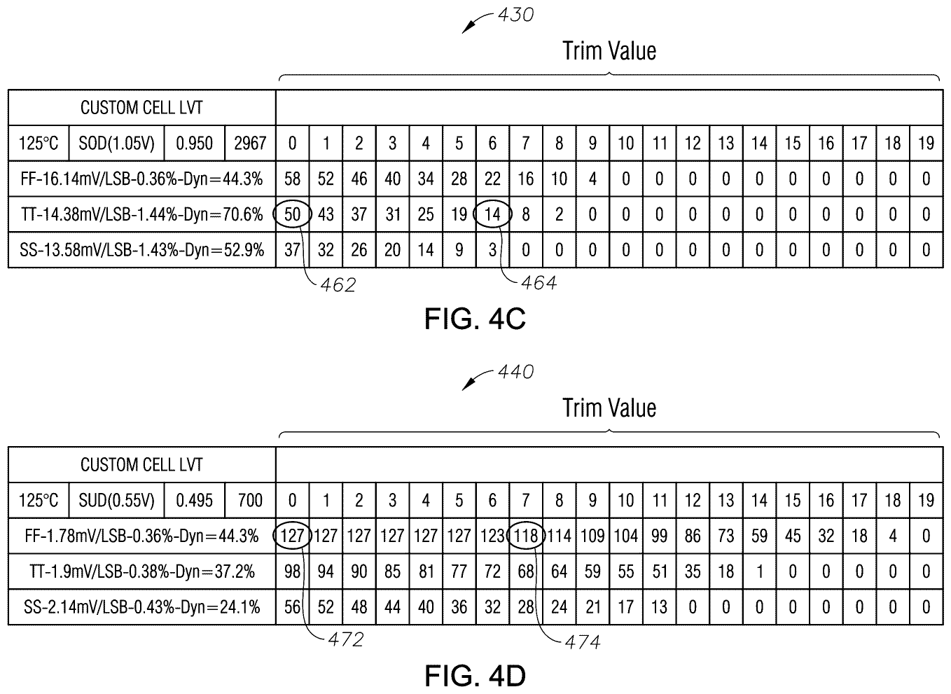

In an example operation, for a predetermined amount of time, the output clock signal (ck) 132 is held at a digital low state (0). Correspondingly, the output o<0>, o<1>, o<2>, o<n−1>, and o<n> of the AND gates 114A, 114B, 114C, 114D, . . . , 114(N−1), and 114N in the delay line 126 are also set to a digital logic low state (0). The setting to a digital logic low state (0) for the AND gates 114A, 114B, 114C, 114D, . . . , 114(N−1), and 114N takes one gate delay (e.g., the time taken for a signal to propagate through a logic gate from its input to its output). Therefore, a digital logic low state (0) propagates through the delay line 126 “quickly” (e.g., approximately one gate delay). Continuing with such an example, in response to the output clock signal (ck) 132 transitioning from a digital logic low state (0) to a digital logic high state (1), the AND gates 114A, 114B, 114C, 114D, . . . , 114(N−1), and 114N transition to the digital logic high state (1) value one after another. For example, after a first delay of first AND gate 114A, output o<0> transitions to a digital logic high state (1), then after a second delay of second AND gate 114B, output o<1> transitions to a digital logic high state (1) and so on down the delay line 126 in response to a measurement window (ti) (see, e.g., FIG. 4A for a timeframe or duration during which measurements or observations are made) being long enough to transition each AND gate to the digital high state. In response to the input clock signal (ckin) 140 transitioning from a digital logic low state (0) to a digital logic high state (1), there is a propagation of the output clock signal (ck) 132 into the delay line 126. Further, in response to a next rising edge of the input clock signal (ckin) 140, flip-flops 130A, 130B, 130C, . . . 130(N−1) and 130N capture a respective transition from digital low state (0) to a high state (1) and output their respective states as thermometer coded output 128.

While the discussion of FIG. 1 is regarding an upfront delay line 116 being used with the droop detection element 112, one or ordinary skill in the art understands the upfront delay line 116 is able to be used with a digital phase lock loop (PLL) (e.g., to comparing the phase difference between the input and output signals to generate an error signal, and indicating the phase difference between the two), a digital delay-locked loop (DLL) (e.g., a circuit used in digital systems to align the phase relationship between different clock signals or to generate precise delays in digital signals), clock synchronization applications, memory interfaces, or the like without departing from the spirit of the implementations.

FIG. 2 is a block diagram representation of an example droop detector circuit 200 with an up-front delay line 216, in accordance with certain implementations. In FIG. 2, similar elements to those of FIG. 1 are not discussed again for the sake of brevity and conciseness.

As illustrated in FIG. 2, the droop detection circuit 200 includes a delay element 218A and a delay element 218B where each delay element of the delay elements 218A and 218B include a non-inverting gate or a non-inverting gate combination (e.g., an input of the delay element having a same digital state as an output of the delay element). Further, the delay elements 218A and 218B are configured to provide a delay to the droop detection element 112 in a similar manner to the delay elements 118A and 118B. Additionally, the delay element 218A is an AND gate and the delay element 218B is an OR gate (generates a digital high state (logic 1) output in response to at least one input being a digital high state (1)).

In certain implementations, the delay element 218A includes one input operably connected to the clock signal (ck) 132 and another input operably connected or tied to a digital high state (1), such as Vdd. In this manner, the delay element 218A becomes a pass-through to the clock signal (ck) 132. To explain further, in response to the clock signal (ck) 132 being a digital logic low state (0), a first delayed clock signal (ckd) 234 is a digital logic low state (0) and in response to the clock signal (ck) 132 being a digital logic high state (1), the first delayed clock signal (ckd) 234 is a digital logic high state (1). Additionally, the first delayed clock signal (ckd) 234 is delayed by one gate delay where the gate is the delay element 218A.

The delay element 218B includes one input operably connected to the first delayed clock signal (ckd) 234 and another input operably connected or tied to a digital logic low state (0), such as Vss (e.g., negative power supply or ground connection). In this manner, the delay element 218B becomes a pass-through to the first delayed clock signal (ckd) 234. Hence, in response to the first delayed clock signal (ckd) 234 being a digital logic low state (0), a second delayed clock signal (ck2d) 236 is a digital logic low state (0) and in response to the first delayed clock signal (ckd) 234 being a digital logic high state (1), then the second delayed clock signal (ck2d) 236 is a digital logic high state (1). Alternatively stated, the second delayed clock signal (ck2d) 236 is the first delayed clock signal (ckd) 234 delayed by one gate delay where the gate is the delay element 218B. One of ordinary skill in the art understands, the delay elements 218A and 218B can be alternated and any combination, such as the delay elements 218A and 218B both being AND gates or the delay elements 218A and 218B both being OR gates, is fully contemplated without departing from the spirit of the implementations. In other configurations (not shown), the delay elements 218A and 218B can be, for example, but not limited to: consecutive NAND gates or consecutive NOR gates providing a non-inverter gate combination); or any other different logic gate combination that provides a resulting non-inverting signal output.

In various implementations, the delay element 218A includes a first VT-type and the delay element 218B includes a second VT-type where the first and the second VT-types are different. For example, the first VT-type is a ULVT or ELVT type where the first VT-type corresponds to a VT-type of the critical path. Additionally, the second VT-type is an SVT type where the second VT-type is configured for low voltage and low clock frequencies. In various implementations, the first VT-type has a lower voltage sensitivity (e.g., lower voltage threshold) than the second VT-type.

FIG. 3 is a block diagram representation of an example droop detector circuit 300 with an example up-front delay line 316, in accordance with certain implementations. In FIG. 3, similar elements to those of FIGS. 1 and 2 are not discussed again for the sake of brevity and conciseness.

As illustrated in FIG. 3, the example droop detector circuit 300 includes sets of delay elements 318A, 318B, 318C, . . . , 318(N−1), and 318N (e.g., delay chain). In various implementations, the sets of delay elements 318A, 318B, 318C, . . . , 318(N−1), and 318N can include a single delay element, a pair of delay elements, a triad of delay elements, and so forth up to an N amount of delay elements where N is a non-negative integer. Additionally, the sets of delay elements 318A, 318B, 318C, . . . , 318(N−1), and 318N per input can include a single delay element, a pair of delay elements in series, a triad of delay elements in series, and so forth up to an N amount of delay elements in series where N is a non-negative integer. Further, the delay elements in the sets of delay elements 318A, 318B, 318C, . . . , 318(N−1), and 318N can be non-inverting logic gates, such as buffers, operational amplifiers, in series inverter pairs, AND gates, OR gates, a combination of these non-inverting logic gates, and the like without departing from the spirit of the implementations. Additionally, the sets of delay elements 318A, 318B, 318C, . . . , 318(N−1), and 318N include an arrangement of first sets of delay elements with a first VT-type and second sets of delay elements with a second VT-type.

In a non-limiting example, sets of delay elements 318A, 318B, and 318C include delay elements with the first VT-type and sets of delay elements 318(N−1), and 318N include delay elements with the second VT-type. Continuing with such an example, the sets of delay elements 318A, 318B, and 318C are ULVT or ELVT type elements where the sets of delay elements 318A, 318B, and 318C have a same or similar VT-type as the critical path. Additionally, the sets of delay elements 318(N−1), and 318N are SVT type elements with a low voltage and low frequency configuration.

In various implementations, the sets of delay elements with the first VT-type are a majority of the sets of delay elements 318A, 318B, 318C, . . . , 318(N−1), and 318N compared to the sets of delay elements with the second VT-type by a percentage in the range of greater than 50% and less than 100%. In various implementations, the sets of delay elements with a VT-type that corresponds to approximately the same or identical voltage threshold (e.g., “close to” the VT-type) of logic gates of the critical path make up between 51% to 99% of the sets of delay elements 318A, 318B, 318C, . . . , 318(N−1), and 318N in comparison to the sets of delay elements with a VT-type configured for low voltage and low frequency operation.

The example droop detector circuit 300 includes a multiplexer 322 configured to transmit a selected clock signal (e.g., one of ck, ck2d, ck4d, ck6d, . . . , ck(n−1)d, or cknd selected by trim input 324) to the delay line 126 (e.g., the delay monitor/telemetry sensor) from a plurality (e.g., a range) of different versions of clock signal ck, ck2d, ck4d, ck6d, . . . , ck(n−1)d, or cknd, where the different versions of the clock signal include the clock signal (ck) 132 and delayed versions of the clock signal (ck2d, ck4d, ck6d, . . . , ck(n−1)d, or cknd). The delayed versions of the clock signal (ck2d, ck4d, ck6d, . . . , ck(n−1)d, or cknd) can be transmitted from an end delay element in a respective set of delay elements. Collectively, the multiplexer 322 is configured to receive the clock signal (ck) 132 at a first input of the multiplexer 322 (i.e., an input 0 of mux); an output (ck2d) of an end delay element of the set of delay elements 318A at a second input of the multiplexer 322 (i.e., an input 1 of mux); an output (ck4d) of an end delay element of the set of delay elements 318B at a third input of the multiplexer 322 (i.e., an input 2 of mux), an output (ck6d) of an end delay element of the set of delay elements 318C at a fourth input of the multiplexer 322 (i.e., an input 3 of mux), an output (ck(n−1)d) of an end delay element of the set of delay elements 318(N−1) at a (n−1)^{th} input of the multiplexer 322 (i.e., an input n−1 of mux), and an output (cknd) of an end delay element of the set of delay elements 318N at a n h input of the multiplexer 322 (i.e., an input n of mux).

In contrast to other approaches, advantageously, the up-front delay lines 116, 216, and 316 are interleaved delay element chains where the multiplexers 122 and 332 selectively choose inputs from connected delay elements in the chain of delay elements. Further, advantageously, the upfront-delay lines 116, 216, and 316 are configured with VT-types that are used in the critical path.

In an example operation, in response to the trim input 324 selecting the output ck6d at the fourth input of the multiplexer 322, the clock signal (ck) 132 can be delayed by six delay elements within the set of delay elements 318A, 318B, and 318C. Additionally, those six delay elements within the set of delay elements 318A, 318B, and 318C can be ULVT type elements that are the same or similar elements in the critical path. Therefore, the code read at the outputs o<0>, o<1>, . . . , o<n−2>, o<n−1>, and o<n>, of the delay line 126 (e.g., delay monitor/telemetry sensor) would behave like devices in the critical path. Additionally, the code output o<0>, o<1>, . . . , o<n−2>, o<n−1>, and o<n> of the delay line 126 would be sensitive to changes in voltage for the droop detection element 112 due to the delay line 126 being made up of voltage sensitive logic gates.

FIG. 4A is a graphical representation 410 of an input clock signal (ckin) 432 to and an example output signal (ck) 444 of a pulse generator and an example output 442 of a delay line, in accordance with certain implementations. FIG. 4B is a graphical representation of an input clock signal (ckin) 432, an example delayed output signal (ck+Xd where X is a non-negative integer representing the number of delay elements propagated through and d is a gate delay) 450 of a pulse generator, and an example output 452 (e.g., corresponding to the thermometer coded output 128) for a delay line, in accordance with certain implementations.

As illustrated in FIG. 4A, the input clock signal (ckin) 432 triggers a pulse generator to produce the example clock signal (ck) 444. In response to a rising edge 440, a digital logic high state (1) propagates through a delay line and the example output 442 is captured before the next rising edge of the input clock signal (ckin) 432. Each time the rising edge 440 occurs in the example clock signal (ck) 444, logic gates, such as flip-flops 130A, 130B, 130C, . . . 130(N−1), and 130N, capture a digital state (e.g., four logic gates switched from a digital logic low state (0) to a digital logic high state (1) as shown in the example output 442).

In response to the example output clock signal (ck) 444 transitioning from a digital logic low state (0) to a digital logic high state (1) at the rising edge 440, logic gates, such as the AND gates 114A, 114B, 114C, 114D, transition to the digital logic high state (1) value one after the other in response to a measurement window (ti) 436 being “long enough” in time to transition four logic gates to the digital logic high state as represented in the example output 442.

As illustrated in FIG. 4B, a graphical representation 420 depicts a measurement window (t1) 438 to be “long enough” in time to only capture two logic gates at a digital high state before a rising edge 448 of an example clock input signal (ckin) 432. Further, the example output clock signal (ck) 444 (FIG. 4A) and the example delayed output signal (ck+Xd) 450 are identical except the example delayed output signal (ck+Xd) 450 is the example output clock signal (ck) 444 delayed (e.g., by Xd). Further, in comparison, the measurement window (ti) 436 is relatively “long” (e.g., greater in time) compared with the measurement window (ti) 438 of FIG. 4B.

FIG. 4C is a table 430 of simulation results for a custom cell low voltage threshold (LVT) delay line at a higher voltage and higher frequency, in accordance with certain implementations. FIG. 4D is a table 440 of simulation results for a custom cell LVT delay line at a lower voltage and lower frequency, in accordance with certain implementations.

As illustrated in FIGS. 4C and 4D, in the Y direction, three different example corners, FF Corner, TT Corner and SS Corner are plotted for a custom cell LVT delay line (e.g., delay monitor/telemetry sensor) at 125° C. (257° F.), supply over droop (SOD) 1.05V, 950 millivolts Vdd, and close to three gigahertz (2.967 gigahertz). FF, TT, and SS are fast, typical, and slow corner and relate to the performance or characteristics of a cell under specific conditions.

FF (Fast Fast) 16.14 mV/LSB (16.14 millivolts per Least Significant Bit) indicates the sensitivity or resolution of the Fast Fast parameter with respect to voltage changes. Alternatively stated, a change of 1 LSB corresponds to a change of approximately 16.14 millivolts in Vdd. Further, 1.7% refers to the per code variation of Vdd with the Fast Fast parameter and dyn=98.6% relates to the dynamic range or the percentage of the overall range where the parameter operates or is effective.

TT (Typical Typical) 14.38 mV/LSB (14.38 millivolts per LSB) indicates the sensitivity or resolution of the Typical Typical parameter concerning voltage changes. Additionally, 1.44% represents the per code variation of Vdd associated with the Typical Typical parameter and dyn=70.6% represents the dynamic range or the effective range where the TT parameter operates, expressed as a percentage.

SS (Slow Slow) 13.58 mV/LSB (13.58 millivolts per LSB) represents the sensitivity or resolution of the Slow Slow parameter concerning voltage changes. Additionally, 1.43% indicates the per code variation of Vdd associated with the Slow Slow parameter and dyn=52.9% indicates the dynamic range or the effective range where the SS parameter operates, expressed as a percentage.

In a non-limiting example of FIG. 4C, in the typical corner (TT) at a trim value of 0 (e.g., the clock signal (ck) 132 includes no delay by the delay elements within the upfront delay line) the code is 50 (reference numeral 462 in FIG. 4C). In various implementations, the trim value corresponds to the trim inputs 124, 324, and the bin2OH code 534 (FIG. 5) for the upfront delay lines 116, 216, 316, and telescoping delay line 504 (FIG. 5). Further, in response to the trim value being zero, the delay elements in the upfront delay lines 116, 216, 316, or the telescoping delay line 504 are not used, and the clock signal (ck) 132 passes through directly to the custom LVT cell (e.g., the delay line). Continuing an example of FIG. 4C, the clock signal (ck) 132 propagates through 50 (reference numeral 462 in FIG. 4C) specialized gates (e.g., thermometer coded output 128 corresponds to 50 (reference numeral 462 in FIG. 4C) in the custom cell of the delay line 126.

In response to increasing the trim value to six, the code decreases from 50 (reference numeral 462 in FIG. 4C) to 14 (reference numeral 464 in FIG. 4C). At a trim value of 6, there is a sensitivity to Vdd that is 1.44% per code variation; this means with a code of 14 (reference numeral 464 in FIG. 4C), that is a 21% voltage droop that is measurable and accurate. Therefore, to maintain an output code from the custom LVT cell, such as the delay line 126, that is “low” (e.g., between 10 and 20), but high enough to measure voltage droop allows for the use of the up-front delay line to be used to track the critical path. One of ordinary skill in the art understands, increasing the trim value from zero to six does not necessarily mean there are six upfront delay elements. For example, in the simulation of FIG. 4C, there are two delay elements for each trimming value (see FIG. 3).

Continuing with such an example, through trimming, the code can be reduced to 14 (reference numeral 464 in FIG. 4C) from 50 (reference numeral 462 in FIG. 4C). By doing so, means 72% of the delay is coming from the up-front delay line, such as the upfront delay lines 116, 216, and 316, having a VT-type the same or similar to (e.g., the logic gates comprising) the critical path. Using equation (1)

$$\frac{code @ trim 0 - code @ trim 6}{code @ trim 0} = 72 \% \qquad ( eq . 1 )$$

Accordingly, 72% of the delay is coming from the delay elements in the up-front delay line having a VT-type of the same or similar to the critical path, and, thus 72% of the delay line behavior is “close to” the critical path. Further, it may be surmised that 28% of the delay is attributed to the specialized delay elements (e.g., at a higher VT-type than the critical path, such as SVT) configured to be sensitive to Vdd. Hence, one custom LVT cell (e.g., the delay monitor/telemetry sensor), such as delay line 126, can track the critical path while still maintaining sensitivity to Vdd on the code (that is “smaller” (e.g., between 10 and 20) in value but high enough to make measurements). Therefore, one custom LVT cell, such as the delay line 126, can function as both a delay monitor and droop detector. In various implementations, advantageously, the delay elements in the up-front delay line are configured to track the critical path with a “high” (e.g., greater than 50%) percentage of accuracy. One of ordinary skill in the art understands that the delay elements in the up-front delay line being configured to track the critical path with an “average” (e.g., greater than 25%) percentage of accuracy is fully contemplated without departing from the spirt of the implementations.

Continuing with such an example in FIG. 4C, in response to the code being 14 (reference numeral 464 in FIG. 4C), the clock signal (ck) has passed through 14 specialized logic gates, such as in the delay line 126, instead of passing through 50 specialized logic gates. As a result, the difference between the two is appropriately attributed to the trimming of the delay in the upfront delay line. In addition, advantageously, by the process of trimming the delay, the clock signal (ck) 132 would pass through a lesser quantity of specialized AND logic gates (e.g., SVT, high VT-type gates) of the delay line 126. Advantageously, by doing so, the behavior of the signal delay would be contained within the delay monitor (e.g., the delay line 126), and is measurable (e.g., since the resultant signal would not “overflow” past the last measurable AND gate of the delay line 126).

In FIG. 4D, the example circuit simulated in FIG. 4C is operated at a low voltage (0.495V) and low frequency (0.7 GHz). In operation, the droop detection circuits 100, 200, 300, and 500 can operate at varying conditions, such as high voltage-high frequency and low voltage-low frequency. In various implementations, the delay monitor/telemetry sensor, such as delay line 126 of the droop detection element 112, provides the flexibility to use the droop detection circuits 100, 200, 300, and 500 at higher voltage-high frequency or at low voltage-low frequency.

As illustrated in FIG. 4D, in the Y direction, three different example corners, FF Corner, TT Corner and SS Corner are plotted for a custom cell LVT up-front delay line at 125° C. (257° F.), supply under droop (SUD) 0.55V, 495 millivolts Vdd, and 700 megahertz. In FF mode, the custom cell LVT of FIG. 4D can cover the FF corner where, at a trim value of zero, the code is 127 (reference numeral 472 in FIG. 4D). For instance, in response to the custom cell including 128 delay elements, the clock signal (ck) 132 “overflows” as it propagates through all the delay elements of the custom cell. Such a scenario can occur when the clock signal (ck) 132 propagates all the way to the end of the custom LVT cell. Accordingly, the droop detection element 112 would not be able to measure anything since the clock signal (ck) 132 has propagated to the end of the custom LVT cell. Therefore, advantageously, since the custom LVT cell is fully utilized (the custom LVT cell is being fully utilized or operating at maximum capacity), a delay can be introduced with a trim value. Moreover, in response to the trim value being changed from 0 to 7, the code has gone down from 127 (reference numeral 472 in FIG. 4D) to 118 (reference numeral 474 in FIG. 4D) (i.e., 9 LSBs). Thus, to get a code that is “smaller,” such as something between 10 and 20, for example, numerous trimming steps would be required. Such a scenario would undoubtedly be undesirable, as additional trimming steps signify more IC board space and additional power consumption to house additional delay elements in a larger delay line.

To prevent requiring numerous trimming steps, according to inventive aspects as described herein, advantageously, VT-type devices can be “mixed” in the upfront delay line (e.g., ULVT type and SVT type devices) using delay devices of an SVT type (e.g., that allow for the decreasing in the code value “faster” (e.g., at higher margins)). Advantageously, as well, by using less delay elements in the upfront delay line, the code can be optimized to decrease “much faster,” and hence, translate to a “smaller” delay line (e.g., fewer delay elements in the upfront delay line).

Accordingly, in an example droop detection circuit, such as the droop detection circuits 100, 200, 300, and 500, there can be at least three different VT-types implementations. First, there can be “regular” gates using sensitivities that are close to the critical path. For example, the ULVT or ELVT type devices. Second, there can be “specialized” gates that are used in the delay line with multiple VT-types. For example, the specialized LVT type. In addition, there can be regular gates that are configured for low voltage and low clock frequencies. For example, the SVT type devices. Advantageously, such an example droop detection circuit may be customized for optimization with regard to a voltage threshold of signal propagation and the size of the delay line.

FIG. 5 is a block diagram representation of an example droop detector circuit 500 with an up-front delay line 516, in accordance with certain implementations. In FIG. 5, similar elements to those of FIGS. 1, 2, and 3 are not discussed again for the sake of brevity and conciseness.

As illustrated in FIG. 5, the example droop detector circuit 500 includes a telescopic delay line 504 comprising delay cells 544A, 544B, 544C, and 544D. In certain examples, by activating one or more delay cells, the telescopic delay line 504 can be configured to transmit a selected clock signal ck, ck2d, ck4d, ck6d, or ck8d (e.g., selected by a binary code 534) to the delay line 126 (e.g., the delay monitor/telemetry sensor) from a plurality (e.g., a range) of different versions of the clock signal ck, ck2d, ck4d, ck6d, or ck8d. Further, the delayed versions of the clock signal ck2d, ck4d, ck6d, or ck8d are transmitted from respective delay cells of the first or the second VT-types. The example droop detector circuit 500 also includes a binary-to-one-hot (bin2OH) device 542 configured to receive the binary code (TRIM <n:0>) 534 and transmit a one hot code signal to the telescopic delay line 504.

As illustrated in FIG. 5, in some implementations, the telescopic delay line 504 can replace the one or more delay elements and the multiplexers in the droop detector circuits 100, 200, and 300 shown in FIGS. 1, 2, and 3. Used in ICs to create precise delays in signals, the telescopic delay line 504 is a type of delay line. Further, useful in applications where there is a need for precise timing or synchronization, telescopic delay lines can be employed in communication systems, signal processing, or clock generation circuits. As the name implies, the telescopic aspect refers to the construction, that involves multiple stages, segments, or cells, such as delay cell 0 544A, delay cell 1 544B, delay cell 2 544C, and delay cell 3 544D, of delay elements cascaded together. Additionally, each delay cell contributes a small increment of delay to the overall delay line. A further characteristic of the telescopic delay line 504 is an ability to provide a wide range of selectable delays by adjusting or activating different delay cells or stages within the telescopic delay line 504. By activating or bypassing specific delay cells, the total delay of the clock signal (ck) 132 propagating through the telescopic delay line 504 may be precisely controlled. One of ordinary skill understands that the delay cells can be implemented using various techniques, such as transmission lines, RC (resistor-capacitor) networks, or switched capacitor circuits, depending on the technology and design conditions without departing from the spirit of the implementations. Advantageously, telescopic delay lines offer flexibility and granularity in adjusting delays, for use in applications that demand precise timing control or signal synchronization. Further, to ensure proper synchronization of signals in complex digital circuits telescopic delay lines provide a method to fine-tune or select delays in electronic systems.

By activating at least one of one or more delay cells the telescopic delay line 504 is configured to delay the clock signal (ck) 132. The delayed clock signal can be determined by the binary-to-one-hot (bin2OH) device 542 that is configured to receive the binary code (TRIM <n:0>) 534 and transmit a one hot code signal to the telescopic delay line 504. Moreover, the binary-to-one-hot (bin2OH) device 542 may be a digital logic component used to convert binary-coded input, such as binary code (TRIM <n:0>) 534, into a one-hot encoded output. In digital systems, as defined herein, binary encoding represents a numerical value using a sequence of binary bits, where one bit is active (set to 1) at a time. Representatively, a one-hot code represents each value in a set with a unique bit pattern, where one bit is active (1) and others are inactive (0). Further, the one-hot encoded output corresponds to the active bit position in the binary input that is produced by the bin2OH device, such as binary-to-one-hot (bin2OH) device 542, from a binary input, such as binary code (TRIM <n:0>) 534. In a non-limiting example, for a 3-bit binary input (e.g., 000, 001, 010, 011, and the like), a bin2OH device produces an 8-bit one-hot encoded output. In response to the binary input being 001 (position 1 being enabled), the output is 00000010, indicating the second bit position is active. For example, by performing a transformation from a binary representation to a one-hot representation in a Bin2OH device 542 allows the telescopic delay line 504 to work with different delay cell schemes for applications.

In various implementations, at least one delay cell includes elements with a first VT-type, at least one delay cell includes elements with a second VT-type, and the first VT-type is different from the second VT-type. According to certain examples, at least one delay cell includes elements with a ULVT type and at least one delay cell includes elements with an SVT type. In certain examples, the delay cells 544A and 544B contain elements of a ULVT type and the delay cells 544C and 544D contain elements of an SVT type. In some examples, the delay cells 544A, 544B, and 544C contain elements of a ULVT type and the delay cell 544D contains elements of an SVT type. In some examples, the delay cell 544A contains elements of a ULVT type and the delay cells 544B, 544C, and 544D contain elements of an SVT type.

Advantageously, the use of the telescopic delay 504 reduces power consumption. Illustratively, according to one example operation, in the upfront delay line 316, the clock signal (ck) 132 propagates all the way to the end of the upfront delay line 316. Therefore, each set of delay elements 318A, 318B, 318C . . . 318(N−1), and 318N in the upfront delay line 316 is switched and that consumes power. In contrast, the telescopic delay line 504 does not use each logic gate in the telescopic delay line 504. For instance, the inputs to each unused logic gate in the telescopic delay line 504 are tied down so as not to switch and consume power.

According to an example operation, the bin2OH device 542 inputs a selection code to the telescopic delay line 504 for Q(0) 546A, Q(1) 546B, Q(2) 546C, or Q(3) 546D. In response to the delay cell 0 544A being selected, the Q(0) 546 is going to be 1 (e.g., a digital high state) and the Q(1) 546B, the Q(2) 546C, and the Q(3) 546D go to 0 (e.g., a digital low state). In response to the delay cell 1 544A being selected, the Q(1) 546B is going to be 1 (digital high state) and all the other inputs go to 0 (digital low state) and so on.

Continuing with an example operation, the Q(0) 546A is 1 (a digital high state) and the Q(1) 546B is 0 (a digital low state), the Q(2) 546C is 0 (a digital low state), and the Q(3) 546D is 0 (a digital low state). In response to the Q(0) 546A being a 1 (digital high state), the second input of an A gate 548 is 1 (digital high state) and a second input of a C gate 550 is 0 (digital low state). As the A gate 548 and the C gate 550 are NAND gates, the A gate 548 is a pass-through to an input 552 (e.g., as one input is a digital high state, no matter the signal on the other input, an inverted input is the output). Inverting the input 552, the A gate 548 transmits the inverted input to a B gate 554, that inverts the input 552 again as output Y (e.g., thus the input 552 is delayed by two gates; the A gate 548 and the B gate 554). Further, the C gate 550 blocks the input 552 (as one input is a digital low state, no matter the signal on the other input, the output is a digital high state as the input 552 is not reproduced). Therefore, the output of the C gate 550 is 1 (digital high state) and the C gate 550 does not toggle. Also, as the upper input of the B gate 554 is a digital low state, the output of the B gate 554 is a digital high state. Thus, the input 552 is going from the A gate 548 then the B gate 554 and then output. Therefore, in response to the Q(0) 546A being selected, the input 552 passes through two gates.

In another example operation, in response to the bin2OH device 542 inputting a selection on the Q(1) 546B there is a digital high state on the Q(1) 546B and the Q(0) 546A, the Q(2) 546C, and the Q(3) 546D are at a digital low state. Blocked at the A gate 548 is the input 552 as a digital low state is on the A gate 548 and the A gate output is a digital high state. Therefore, there is a digital high state at the B gate 554 that is a pass-through to the other input. As the A gate 548 is not used, the input 552 passes to the C gate 550. The C gate 550 (also a pass-through) inverts the input 552 and transmits the output to an A gate 558. The A gate 558 inverts the input 552 again, and transmits the output to a B gate 556. The B gate 556 inverts the input 552 again, and transmits the output to the B gate 554. The B gate 554 inverts the input 552 yet again for a total of four logic gates instead of two total logic gates at the Q(0) 546A being selected. Further, in response to selecting the Q(1) 546B, the delay cell 1 544B and the delay cell 0 544A can be used, but the delay cell 2 544C and the delay cell 3 544D may not switch at all. Further, the inputs to the delay cell 2 544C and the delay cell 3 544D can be “standing still” (e.g., the gates are not toggling and power would be conserved).

Deductively, for example, in response to the bin2OH device 542 inputting a selection on the Q(2) 546C, the input 552 would propagate through a total of six logic gates. Further, in response to the bin2OH device 542 inputting a selection on the Q(3) 546D, the input 552 propagates through a total of eight logic gates.

In the example droop detector circuit 500 where four delay cells are in the telescopic delay line 504, one of ordinary skill in the art understands many more delay cells can be used without departing from the spirit of the implementations. Further, one of ordinary skill in the art understands fewer delay cells can be used, such as two delay cells, without departing from the spirit of the implementations

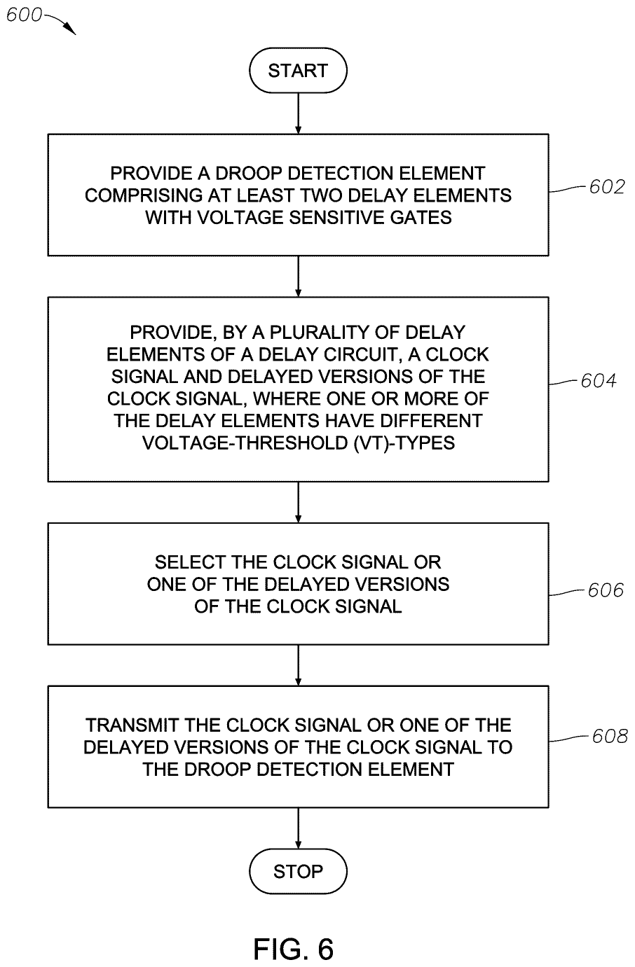

FIG. 6 illustrates an example procedure 600 for precision alignment/trimming of a clock signal to the behavior of a critical path, in accordance with certain implementations. While FIG. 6 shows a sequence of steps in the example procedure 600, one of ordinary skill in the art understands that any order of sequences is possible without departing from the spirit of the implementations. The example procedure 600 may be performed with each of the implementations in FIGS. 1, 2, 3 and 5. The sequence shown for the example procedure 600 is provided as an example for the reader's understanding.

In block 602 of the example procedure 600, a droop detection element comprising at least two delay elements having voltage sensitive gates is provided. As one example, with reference to various implementations as described in FIG. 1, the droop detection element 112 includes voltage sensitive logic gates, such as the AND gates 114A, 114B, 114C, 114D, . . . , 114(N−1), and 114N, of the delay line 126 (e.g., the delay monitor/telemetry sensor).

In block 604 of the example procedure 600, a clock signal (ck) and delayed versions of clock signal (ck+Xd) can be provided by at least two delay elements, where one or more of the delay elements have different VT-types (e.g., different voltage sensitivities). For instance, with reference to various implementations as described in FIG. 1, the clock signal (ck) 132, the first delayed clock signal (ckd) 134 provided by the delay element 118A, and the second delayed clock signal (ck2d) 136 can be provided by the delay element 118B, where the delay element 118A and the delay element 118B have different VT-types.

In block 606 of the example procedure 600, a clock signal (ck) or one of delayed versions of the clock signal are selected by a selection device. For instance, with reference to various implementations as described in FIG. 1, the clock signal (ck) 132, the first delayed clock signal (ckd) 134, or the second delayed clock signal (ck2d) 136 are selected by the multiplexer 122.

In block 608 of the example procedure 600, a clock signal (ck) or one of delayed versions of the clock signal can be transmitted to the droop detection element. For instance, with reference to various implementations as described in FIG. 1, the clock signal (ck) 132, the first delayed clock signal (ckd) 134, or the second delayed clock signal (ck2d) 136 can be transmitted to the droop detection element 112.

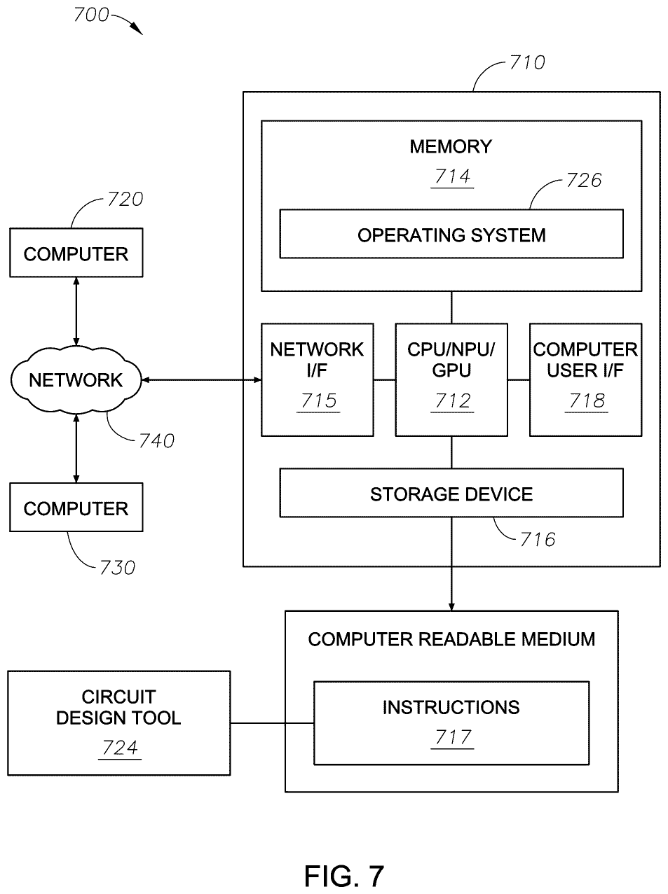

FIG. 7 illustrates example hardware components in the computer system 700 that may be used to precisely align/trim a clock signal to the behavior of a critical path. In certain implementations, the example computer system 700 (e.g., networked computer system and/or server) may include circuit design tool 724 and execute software based on the procedure as described with reference to procedure 600 in FIG. 6. In certain implementations, the circuit design tool 724 may be included as a feature of an existing compiler software program.

The circuit design tool 724 may provide generated computer-aided physical layout designs for droop detector circuits. The procedure 600 may be stored as program code as instructions 717 in the computer readable medium of the storage device 716 (or alternatively, in memory 714) that may be executed by the computer 710, or networked computers 720, 730, other networked electronic devices (not shown) or a combination thereof. In certain implementations, each of the computers 710, 720, 730 may be any type of computer, computer system, or other programmable electronic device. Further, each of the computers 710, 720, 730 may be implemented using one or more networked computers, e.g., in a cluster or other distributed computing system.

In certain implementations, the system 700 may be used with semiconductor integrated circuit (IC) designs that contain all standard cells, all blocks or a mixture of standard cells and blocks. In a particular example implementation, the system 700 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 700 may be stored in one or more of memory 714 or storage devices 716 of computer 710 or in networked computers 720, 730.

The system 700 may perform the following functions automatically, with variable user input: determination of read current requirements/thresholds, determination of leakage current requirements/thresholds, identification of logic designs (i.e., periphery circuit designs (i.e., logic threshold voltages, threshold voltage implant layers)), determination of a desired threshold voltage—combination, determination of minimum voltage assist requirements, identification of bit-cell types, determination of memory specific optimization modes (memory optimization mode), floor-planning, including generation of cell regions sufficient to place all standard cells; standard cell placement; power and ground net routing; global routing; detail routing and pad routing. In some instances, such functions may be performed substantially via user input control. Additionally, such functions can be used in conjunction with the manual capabilities of the system 700 to produce the target results that are required by a designer. In certain implementations, the system 700 may also provide for the capability to manually perform functions such as: cell region creation, block placement, pad, and cell placement (before and after automatic placement), net routing before and after automatic routing and layout editing. Moreover, verification functions included in the system 700 may be used to determine the integrity of a design after, for example, manual editing, design rule checking (DRC) and layout versus schematic comparison (LVS).

In one implementation, the computer 710 includes a central processing unit (CPU) 712 having at least one hardware-based processor coupled to a memory 714. The memory 714 may represent random access memory (RAM) devices of main storage of the computer 710, supplemental levels of memory (e.g., cache memories, non-volatile or backup memories (e.g., programmable or flash memories)), read-only memories, or combinations thereof. In addition to the memory 714, the computer system 700 may include other memory located elsewhere in the computer 710, such as cache memory in the CPU 712, as well as any storage capacity used as a virtual memory (e.g., as stored on a storage device 716 or on another computer coupled to the computer 710).

The computer 710 may further be configured to communicate information externally. To interface with a user or operator (e.g., a circuit design engineer), the computer 710 may include a user interface (I/F) 718 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 710 may include a network interface (I/F) 715 which may be coupled to one or more networks 740 (e.g., a wireless network) to enable communication of information with other computers and electronic devices. The computer 710 may include analog and/or digital interfaces between the CPU 712 and each of the components 714, 715, 716, and 718. Further, other non-limiting hardware environments may be used within the context of example implementations.

The computer 710 may operate under the control of an operating system 726 and may execute or otherwise rely upon various computer software applications, components, programs, objects, modules, data structures, etc. (such as the programs associated with the procedure 600 and related software). The operating system 726 may be stored in the memory 714. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 726 in the example of FIG. 7 is shown in the memory 714, but components of the aforementioned software may also, or in addition, be stored at non-volatile memory (e.g., on storage device 716 (data storage) and/or the non-volatile memory (not shown). Moreover, various applications, components, programs, objects, modules, and the like may also execute on one or more processors in another computer coupled to the computer 710 via the network 740 (e.g., in a distributed or client-server computing environment) where the processing to implement the functions of a computer program may be allocated to multiple computers 720, 730 over the network 740.

In example implementations, circuit diagrams have been provided in FIGS. 1-3, and 5 whose redundant description has not been duplicated in the related description of analogous circuit diagrams. It is expressly incorporated that the same cell layout diagrams with identical symbols and/or reference numerals are included in each of embodiments based on its corresponding figure(s).

Although one or more of FIGS. 1-6 may illustrate systems, apparatuses, or methods according to the teachings of the disclosure, the disclosure is not limited to these illustrated systems, apparatuses, or methods. One or more functions or components of any of FIGS. 1-6 as illustrated or described herein may be combined with one or more other portions of another of FIGS. 1-6. Accordingly, no single implementation described herein should be construed as limiting and implementations of the disclosure may be suitably combined without departing from the teachings of the disclosure.

Aspects of the present disclosure may be incorporated in a system, a method, and/or a computer program product. The computer program product may include a computer-readable storage medium (or media) having computer-readable program instructions thereon for causing a processor to carry out aspects of the present disclosure. The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. For example, the memory 714, the storage device 716, or both, may include tangible, non-transitory computer-readable media, or storage devices.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus, or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

The subject matter of the claims is not limited to the implementations and illustrations provided herein, the intention is that modified forms of those implementations including portions of implementations and combinations of elements of different implementations be in accordance with the claims. In the development of any such implementation, there is an appreciation as in any engineering or design project, that numerous implementation-specific decisions are made to achieve the developers' specific goals, such as compliance with system-related and business-related constraints, that vary from one implementation to another. Moreover, while such a development effort is complex and time consuming, there is an appreciation for those of ordinary skill having benefit of these implementations the development would nevertheless be a routine undertaking of design, fabrication, and manufacture.

Reference has been made in detail to various implementations, examples of that are illustrated in the accompanying drawings and figures. In the above description, numerous specific details are set forth to provide a thorough understanding of the implementations provided herein. However, the implementations provided herein can be practiced without these specific details. In some other instances, well-known methods, procedures, components, circuits, and networks have not been described in detail so as not to unnecessarily obscure details of the implementations.

Although the terms first, second, and the like are used herein to describe various elements, these elements should not be limited by these terms. These terms are used to distinguish one element from another. For example, a first element can be termed a second element, and, similarly, a second element is able to be termed a first element. The first element and the second element are both elements, respectively, but they are not to be considered the same element.

The terminology used in the description of the implementations provided herein is for the purpose of describing implementations and is not intended to limit the implementations provided herein. As used in the description of the implementations provided herein and appended claims, the singular forms a, an, and the are intended to include the plural forms as well, unless the context clearly indicates otherwise. The term and/or as used herein refers to and encompasses all possible combinations of one or more of the associated listed items. The terms includes, including, comprises, and/or comprising, when used in this specification, specify a presence of stated features, integers, steps, operations, elements, and/or components, but do not preclude the presence or addition of one or more other features, integers, steps, operations, elements, components and/or groups thereof.

As used herein, the term if may be construed to mean when or upon or in response to determining or in response to detecting, depending on the context. Similarly, the phrase if it is determined or if [a stated condition or event] is detected may be construed to mean upon determining or in response to determining or upon detecting [the stated condition or event] or in response to detecting [the stated condition or event], depending on the context. The terms up and down; upper and lower; upwardly and downwardly; below and above; and other similar terms indicating relative positions above or below a given point or element are used in connection with some implementations of various technologies described herein.

While the foregoing is directed to implementations of various techniques described herein, other, and further implementations can be devised in accordance with the implementations herein, that may be determined by the claims that follow. Although the subject matter has been described in language specific to structural features and/or methodological acts, the subject matter defined in the appended claims is not necessarily limited to the specific features or acts described above. Rather, the specific features and acts described above are disclosed as example forms of implementing the claims.

What is claimed is:

1. A circuit comprising:
a droop detection element comprising voltage sensitive gates; and
at least two delay elements, wherein:
each delay element of the at least two delay elements is a non-inverting gate or a non-inverting gate combination, and wherein:
at least a first delay element comprises a first voltage-threshold (VT)-type;
at least a second delay element comprises a second VT-type; and
the first and the second VT-types are different; and
wherein the at least two delay elements are configured to provide a delay to the droop detection element.

2. The circuit of claim 1, wherein:
the first VT-type comprises an ultra-low voltage threshold (ULVT) type or an extra-low voltage threshold (ELVT) type;
the second VT-type comprises a standard voltage threshold (SVT) type, and
the first VT-type comprises a lower voltage sensitivity than the second VT-type.

3. The circuit of claim 1, wherein the delay element comprises a buffer.

4. The circuit of claim 1, wherein the delay element comprises an AND gate or an OR gate.

5. The circuit of claim 1, further comprising:
a multiplexer configured to transmit one of:
a clock signal to a delay line circuit;
a delayed clock signal transmitted from the first delay element of the first VT-type to the delay line circuit; or
a delayed clock signal transmitted from the second delay element of the second VT-type to the delay line circuit, wherein an input of the second delay element of the second VT-type is coupled to the output of the first delay element of the first VT-type.

6. The circuit of claim 5, wherein the multiplexer configured to receive:
the clock signal at a first input of the multiplexer;
the output of the first delay element at a second input of the multiplexer; and
the output of the second delay element at a third input of the multiplexer.

7. The circuit of claim 1, wherein:
the at least two delay elements are a plurality of the delay elements; and
the plurality of the delay elements comprises an arrangement of first delay elements and an arrangement of second delay elements, wherein:
the arrangement of the first delay elements and the arrangement of the second delay elements comprise at least one of:
one or more single first delay elements and one or more single second delay elements;
one or more pairs of first delay elements and one or more pairs of second delay elements; or
one or more triads of first delay elements and one or more triads of second delay elements.

8. The circuit of claim 7, wherein a majority of the plurality of the delay elements comprise an ultra-low voltage threshold (ULVT) type.

9. The circuit of claim 7, further comprising:
a multiplexer configured to transmit a selected clock signal to a delay line circuit from a plurality of different versions of the clock signal, wherein the different versions comprise at least a clock signal and one or more delayed versions of the clock signal.

10. The circuit of claim 9, wherein:
the one or more delayed versions of the clock signal are transmitted from respective delay elements of the first or the second VT-types.

11. The circuit of claim 9, wherein the multiplexer configured to receive at least:
the clock signal at a first input of the multiplexer;
an output of a first arrangement of the arrangement of first delay elements at a second input of the multiplexer; or
an output of a first arrangement of the arrangement of second delay elements at a third input of the multiplexer.

12. The circuit of claim 9, wherein the multiplexer is configured to receive:
an output of the first arrangement of the first delay elements in combination with an output of a second arrangement of the first delay elements at a third input of the multiplexer; or
an output of the second arrangement of the first delay elements in combination with an output of a second arrangement of the second delay elements at a fourth input of the multiplexer.

13. The circuit of claim 1, wherein:
the at least two delay elements comprise a telescopic delay line, wherein:
the telescopic delay line comprises at least first and second delay cells of two or more delay cells; and
the telescopic delay line, by activating at least two of the one or more delay cells, is configured to transmit a selected clock signal to a delay line circuit from a plurality of different versions of the clock signal, wherein the different versions comprise at least the clock signal and one or more delayed versions of the clock signal.

14. The circuit of claim 13, wherein:
the delayed versions of the clock signal are transmitted from respective delay cells of the first or the second VT-types.

15. The circuit of claim 13, further comprising:
a binary-to-one-hot (bin2OH) device configured to receive a binary code (TRIM <n:0>) and transmit a one hot code signal to the telescopic delay line.

16. The circuit of claim 13, wherein:
at least a first delay cell comprises the first VT-type; and
at least a second delay cell comprises the second VT-type.

17. A method comprising:
providing a droop detection element comprising at least two delay elements with voltage sensitive gates;
providing, by the at least two delay elements, a clock signal and delayed versions of the clock signal, wherein one or more of the delay elements have different voltage-threshold (VT)-types;
selecting the clock signal or one of the delayed versions of the clock signal; and
transmitting the clock signal or the one of the delayed versions of the clock signal to the droop detection element.

18. The method of claim 17, wherein the different VT-types comprises an ultra-low voltage threshold (ULVT) type, an extra-low voltage threshold (ELVT) type, or a standard voltage threshold (SVT) type.

19. The method of claim 18, wherein a majority of the plurality of the delay elements comprise a ULVT type.

20. A computing system, comprising:
one or more processors; and
at least one memory comprising program instructions executable by the one or more processors to:
providing a droop detection element comprising a plurality of delay elements with voltage sensitive gates;
providing, by a plurality of delay elements of a delay circuit, a clock signal and delayed versions of the clock signal, wherein one or more of the delay elements have different voltage-threshold (VT)-types;
selecting the clock signal or one of the delayed versions of the clock signal; and
transmitting the clock signal or the one of the delayed versions of the clock signal to the droop detection element.
